(19) United States
(12) Patent Application Publication
(10) Pub. No.: US 2009/0175065 A1
(43) Pub. Date: Jul. 9, 2009

(54) SEMICONDUCTOR MEMORY DEVICE AND METHOD FOR FABRICATING THE SAME

(76) Inventors: Yoshiaki NAKAO, Osaka (JP); Yasushi GOHOU, Osaka (JP); Shunichi IWANARI, Kyoto (JP); Yasuo MURAKUKI, Kyoto (JP); Masanori MATSUURA, Osaka (JP)

Correspondence Address: MCDERMOTT WILL & EMERY LLP, 600 13TH STREET, NW, WASHINGTON, DC, 20005-3096, US

(21) Appl. No.: 12/259,639

(22) Filed: Oct. 28, 2008

(30) Foreign Application Priority Data
Jan. 9, 2008 (JP) 2008-002309

(51) Int. Cl. G11C 11/22; G11C 17/16; H01S 4/00; G11C 7/00

(52) U.S. Cl. 365/145; 365/225.7; 29/592.1; 365/189.011

(57) ABSTRACT

A semiconductor memory device including a ferroelectric memory includes: a nonvolatile memory having higher data retention capability under high temperature than the ferroelectric memory; and a connection circuit for switching between connection and disconnection of the ferroelectric memory and the nonvolatile memory. The ferroelectric memory receives, through the connection circuit, at least part of data which is unique to the device and which has been written into the nonvolatile memory, and retains the received data.

### CROSS REFERENCE TO RELATED APPLICATION

This application claims priority under 35 U.S.C. §119 on Patent Application No. 2008-2309 filed in Japan on Jan. 9, 2008, the entire contents of which are hereby incorporated by reference.

### BACKGROUND OF THE INVENTION

1. Field of the Invention

The present invention relates to a semiconductor memory device including a ferroelectric memory, and particularly relates to a technique for protecting data in a ferroelectric memory during fabrication process.

2. Description of the Related Art

Semiconductor memory devices including a ferroelectric memory are generally fabricated through the following process steps. First, elements such as ferroelectric memories and control circuits are formed on a wafer. After the elements are formed, a performance test is conducted while the elements are on the wafer. After the performance test, information unique to each chip, such as a chip ID, is written into a predetermined area in each ferroelectric memory. After the writing of the information unique to the chip, each chip is packaged and assembled. After the assembly, a performance test is conducted, and each semiconductor memory device (the ferroelectric memory chip) including the ferroelectric memory is complete.

What becomes a problem here is that the ferroelectric memory is temporarily subjected to high temperatures during the above-described assembly process. Residual polarization (or hysteresis characteristics) in ferroelectric memory is temperature dependent. Thus, the more the ferroelectric memory is subjected to high temperatures, the more the residual polarization is decreased. Due to this, even if the information unique to the chip has been written so that sufficient residual polarization occurs, the residual polarization is reduced by the subsequent heat treatment, causing the read margin to be decreased. As a result, the chip ID and other information unique to the chip cannot be read, and thus the data is substantially lost.

Conventionally, data with opposite logic levels are written into a ferroelectric memory so as to maintain a margin for reading data from the ferroelectric memory, thereby preventing loss of the data even if imprinting proceeds due to a heat treatment (see, for example, Japanese Laid-Open Publication No. 2004-171620 (pp. 4-6, FIG. 1)).

### SUMMARY OF THE INVENTION

In view of the above problem, it is an object of the present invention to prevent information written into a ferroelectric memory from being lost due to a heat treatment in the fabrication process of the ferroelectric memory by using an approach different from the conventional technique.

In order to achieve the object, an inventive semiconductor memory device including a ferroelectric memory includes: a nonvolatile memory having higher data retention capability under high temperature than the ferroelectric memory; and a connection circuit for switching between connection and disconnection of the ferroelectric memory and the nonvolatile memory. The ferroelectric memory receives, through the connection circuit, at least part of data which is unique to the device and which has been written into the nonvolatile memory, and retains the received data. Also, an inventive method for fabricating a semiconductor memory device including a ferroelectric memory includes: a first step of forming the ferroelectric memory and a nonvolatile memory on a chip, the nonvolatile memory having higher data retention capability under high temperature than the ferroelectric memory; a second step of writing data which is unique to the chip into the nonvolatile memory after the first step has been performed; a third step of packaging and assembling the chip after the second step has been performed; and a fourth step of transferring at least part of the data from the nonvolatile memory to the ferroelectric memory after the third step has been performed.

According to the present invention, in the completed semiconductor memory device, the information unique to the device that has been written during the fabrication process of the device is retained in the ferroelectric memory without being lost, and can be correctly read from the ferroelectric memory.

### BRIEF DESCRIPTION OF THE DRAWINGS

FIG. 1 illustrates the configuration of a semiconductor memory device according to a first embodiment of the invention.

FIG. 2 is a flow chart showing process steps for fabricating the semiconductor memory device according to the first embodiment.

FIG. 3 illustrates the configuration of a semiconductor memory device according to a second embodiment of the invention.

FIG. 4 illustrates the configuration of a semiconductor memory device according to a third embodiment of the invention.

FIG. 5 illustrates the configuration of a semiconductor memory device according to a fourth embodiment of the invention.

FIG. 6 illustrates the configuration of a semiconductor memory device in which a separate nonvolatile memory is provided as an area (shown in FIG. 5) for storing the number of times data is written.

### DETAILED DESCRIPTION OF THE INVENTION

Hereinafter, the preferred embodiments of the present invention will be described with reference to the accompanying drawings.

### First Embodiment

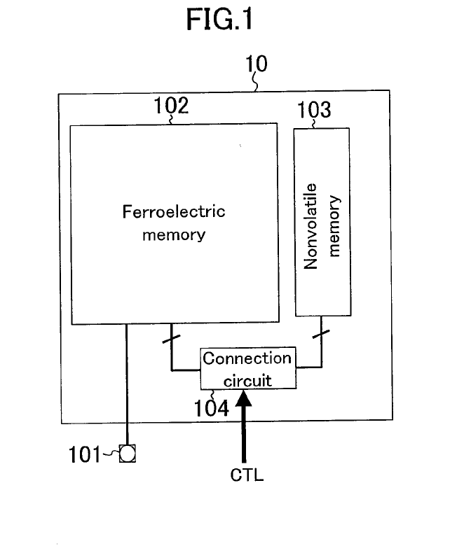

FIG. 1 illustrates the configuration of a semiconductor memory device (which will be hereinafter also referred to simply as a “chip”) according to a first embodiment. In the chip 10 according to this embodiment, a terminal 101 is for reading data from and writing data to a ferroelectric memory 102. A nonvolatile memory 103 has higher data retention capability under high temperature than the ferroelectric memory 102. To be specific, the nonvolatile memory 103 may be composed of physically disconnectable fuses (physical fuses), electrically disconnectable fuses (e-fuses), a nonvolatile memory (a CMOS nonvolatile memory) including CMOS transistors, or the like, or in some cases the nonvolatile memory 103 may be configured by combining these elements. A connection circuit 104 switches between connection and disconnection of the ferroelectric memory 102 and the nonvolatile memory 103 in accordance with a control signal CTL.

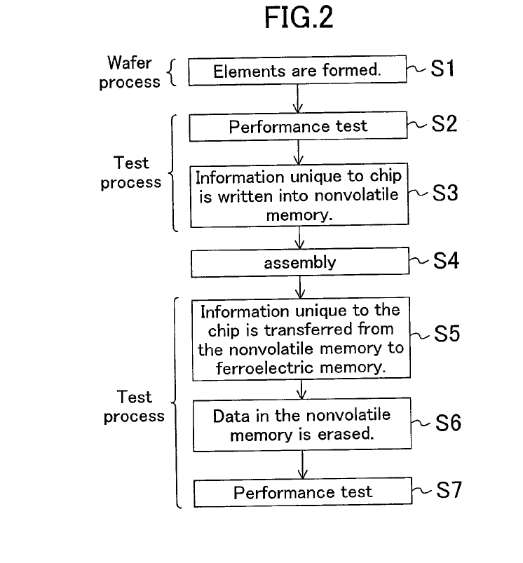

FIG. 2 shows the process flow for fabricating the chip 10. First, each element of the chip 10 is formed on a wafer (S1). After the elements are formed, a performance test is conducted while the elements are on the wafer (S2). After the performance test, information (data) unique to the chip 10, including an ID of the chip 10, is written into the nonvolatile memory 103 (S3). Specifically, in the case of physical fuses, data is written into the nonvolatile memory 103 by disconnecting a desired part of the nonvolatile memory 103. In the case of e-fuses, data is written into the ferroelectric memory 102 from the terminal 101, the connection circuit 104 is controlled to connect the ferroelectric memory 102 and the nonvolatile memory 103, and then a desired part of the nonvolatile memory 103 is disconnected according to the data written into the ferroelectric memory 102, thereby writing the data into the nonvolatile memory 103. In the case of a CMOS nonvolatile memory, data is written into the ferroelectric memory 102 from the terminal 101, the connection circuit 104 is controlled to connect the ferroelectric memory 102 and the nonvolatile memory 103, and then the data written into the ferroelectric memory 102 is transferred to the CMOS nonvolatile memory, thereby writing the data into the nonvolatile memory 103.

After the data is written into the nonvolatile memory 103, the chip 10 is packaged and assembled (S4). After the assembly, the connection circuit 104 is controlled to connect the ferroelectric memory 102 and the nonvolatile memory 103, and then all or part of the data is transferred from the nonvolatile memory 103 to the ferroelectric memory 102 (S5).

Preferably, after the data transfer, the data in the nonvolatile memory 103 is erased (S6). To erase the data, identical data is written into the nonvolatile memory 103 (for example, all are set to “0”), or random data is written into the nonvolatile memory 103. Specifically, in the case of e-fuses, data is written into the ferroelectric memory 102 from the terminal 101, the connection circuit 104 is controlled to connect the ferroelectric memory 102 and the nonvolatile memory 103, and then the data is erased by disconnecting all or a randomly selected part of the nonvolatile memory 103 in accordance with the data written into the ferroelectric memory 102. In the case of a CMOS nonvolatile memory, data having a certain value (e.g., “1”) or having a random value is written into the ferroelectric memory 102 from the terminal 101, the connection circuit 104 is controlled to connect the ferroelectric memory 102 and the nonvolatile memory 103, and then the data is erased by transferring the data written into the ferroelectric memory 102 to the CMOS nonvolatile memory. After the data in the nonvolatile memory 103 is erased, a performance test is conducted (S7), and the chip 10 is complete.

To check the data written into the nonvolatile memory 103, the connection circuit 104 is controlled to connect the ferroelectric memory 102 and the nonvolatile memory 103, and then the data in the nonvolatile memory 103 is transferred to the ferroelectric memory 102. Thereafter, the connection circuit 104 is controlled to disconnect the ferroelectric memory 102 and the nonvolatile memory 103 from each other, and then the data transferred to the ferroelectric memory 102 is read from the terminal 101. The ferroelectric memory 102 and the nonvolatile memory 103 may be disconnected from each other after the data is read from the terminal 101.

As described above, according to this embodiment, in the completed semiconductor memory device 10, the information unique to the device written during the fabrication process of the device is retained in the ferroelectric memory 102 without being lost, and can be correctly read from the ferroelectric memory 102. Moreover, by erasing the contents of the nonvolatile memory 103, it is possible to prevent leakage of the important information temporarily written into the nonvolatile memory 103 during the fabrication process, thereby ensuring security.

### Second Embodiment

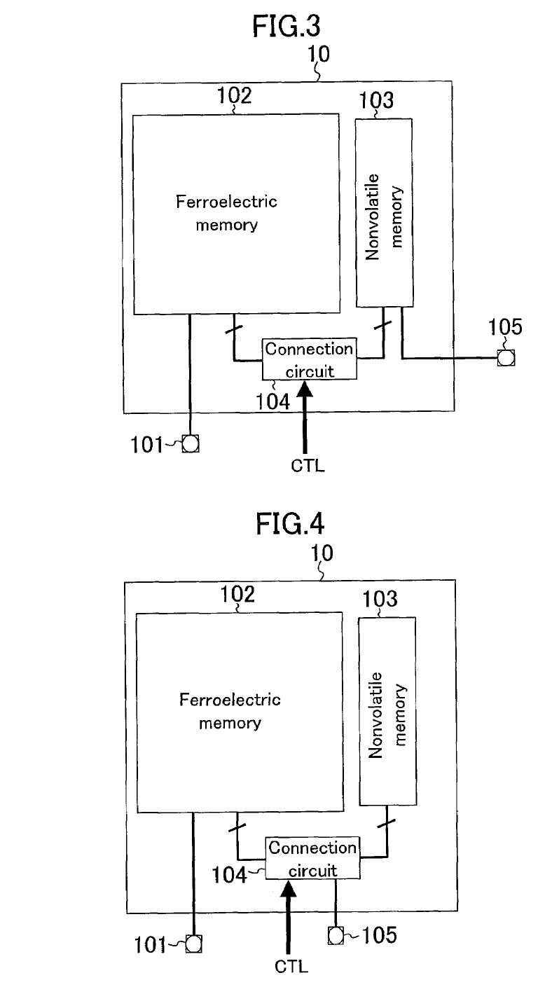

FIG. 3 illustrates the configuration of a semiconductor memory device according to a second embodiment. The chip 10 according to this embodiment has a configuration obtained by adding a terminal 105, which is capable of accessing a nonvolatile memory 103, to the semiconductor memory device of the first embodiment. In this embodiment, it is possible to directly read data written into the nonvolatile memory 103 from the terminal 105 not through a ferroelectric memory 102 and check the data. Furthermore, in a case in which the nonvolatile memory 103 includes e-fuses or a CMOS nonvolatile memory, data to be written into the nonvolatile memory 103 is directly input from the terminal 105 not through the ferroelectric memory 102.

### Third Embodiment

FIG. 4 illustrates the configuration of a semiconductor memory device according to a third embodiment. The chip 10 according to this embodiment has a configuration obtained by connecting the terminal 105 of the semiconductor memory device of the second embodiment with a connection circuit 104 instead of a nonvolatile memory 103. The connection circuit 104 switches between the connection of a ferroelectric memory 102 and the nonvolatile memory 103 and the connection of the nonvolatile memory 103 and the terminal 105. In the second embodiment, a data bus for connecting the nonvolatile memory 103 and the terminal 105 is necessary, whereas in this embodiment, such a data bus is not needed. Thus, in this embodiment, the chip area is reduced as compared with the second embodiment.

### Fourth Embodiment

FIG. 5 illustrates the configuration of a semiconductor memory device according to a fourth embodiment. The chip 10 according to this embodiment has a configuration obtained by adding a limiter circuit 106 to the semiconductor memory device of the first embodiment. This embodiment will be described only in terms of its differences from the first embodiment.

A nonvolatile memory 103 has a dedicated area for retaining the number of times data is written into the nonvolatile memory 103. After data is written into the nonvolatile memory 103, the number of times data is written is incremented, and the incremented number is written into that dedicated area. The limiter circuit 106 refers to the number retained in the dedicated area, and when the number exceeds a predetermined value, the limiter circuit 106 instructs a control circuit 104 to disconnect a ferroelectric memory 102 and the nonvolatile memory 103 from each other.

As described above, in this embodiment, after data is written into the nonvolatile memory 103 a predetermined number of times, access from outside is limited. This eliminates such risk as manipulation of the data in the nonvolatile memory 103 by a third person.

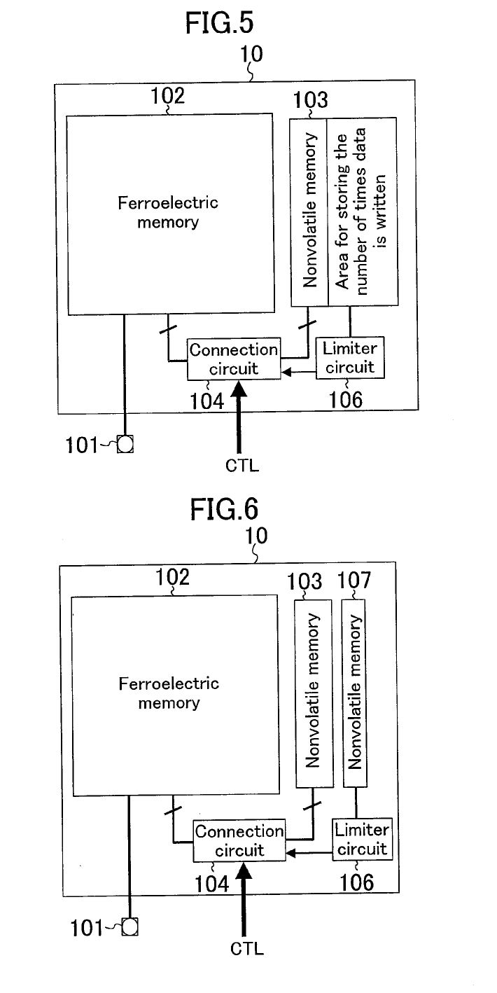

It should be noted that the limiter circuit 106 may be incorporated into the second and third embodiments. Also, as shown in FIG. 6, a separate nonvolatile memory 107 may be provided as the dedicated area for retaining the number of times data is written into the nonvolatile memory 103. In that case, the nonvolatile memories 103 and 107 may be composed of different memories (for example, e-fuses and a CMOS nonvolatile memory).

Furthermore, in the foregoing embodiments, a microcomputer, which is able to access the ferroelectric memory 102 or the nonvolatile memory 103 and which provides the control signal CTL to the connection circuit 104, may be added. That is, data that is input and output between the ferroelectric memory 102 and the nonvolatile memory 103, and the control signal CTL may be generated or processed within the chip 10. This allows the terminals 101 and 105 and the input terminal (not shown) for the control signal CTL to be omitted.

In the semiconductor memory devices according to the present invention, information unique to each device written during the fabrication process is retained in such a state as being readable into a ferroelectric memory even after heat treatment, and thus the inventive semiconductor memory devices are applicable to IC cards fabricated through heat treatment such as infrared reflow, and the like.

What is claimed is:

1. A semiconductor memory device including a ferroelectric memory, comprising:
a nonvolatile memory having higher data retention capability under high temperature than the ferroelectric memory; and
a connection circuit for switching between connection and disconnection of the ferroelectric memory and the nonvolatile memory,
wherein the ferroelectric memory receives, through the connection circuit, at least part of data which is unique to the device and which has been written into the nonvolatile memory, and retains the received data.

2. The device of claim 1, wherein the connection circuit switches between connection and disconnection of the ferroelectric memory and the nonvolatile memory according to a control signal.

3. The device of claim 1, comprising a terminal which is capable of accessing the nonvolatile memory.

4. The device of claim 1, comprising a terminal connected with the connection circuit,
wherein the connection circuit switches between the ferroelectric memory and the terminal as a point to which the nonvolatile memory is connected.

5. The device of claim 1, comprising a limiter circuit for limiting writing data into the nonvolatile memory when a number of times data is written into the nonvolatile memory exceeds a predetermined value.

6. The device of claim 5, wherein the nonvolatile memory retains the number of times data is written into the nonvolatile memory.

7. The device of claim 6, comprising a second nonvolatile memory which has higher data retention capability under high temperature than the ferroelectric memory and which retains the number of times data is written into the nonvolatile memory.

8. The device of claim 7, wherein the second nonvolatile memory includes at least either electrically disconnectable fuses or a nonvolatile memory including CMOS transistors.

9. The device of claim 1, wherein the nonvolatile memory includes at least physically disconnectable fuses, electrically disconnectable fuses, or a nonvolatile memory including CMOS transistors.

10. The device of claim 1, wherein the nonvolatile memory is in a state in which contents thereof have been erased after completion of a data transfer to the ferroelectric memory.

11. The device of claim 10, wherein the nonvolatile memory includes either physically disconnectable fuses or electrically disconnectable fuses, and is in a state in which all of the fuses or a randomly selected fuse therein has been disconnected after completion of a data transfer to the ferroelectric memory.

12. The device of claim 10, wherein the nonvolatile memory includes a nonvolatile memory including CMOS transistors, and is in a state in which contents thereof have been overwritten with identical data or random data after completion of a data transfer to the ferroelectric memory.

13. The device of claim 10, wherein the nonvolatile memory includes physically disconnectable fuses and electrically disconnectable fuses, and is in a state in which at least either of the physically disconnectable fuses or the electrically disconnectable fuses, all of the fuses or a randomly selected fuse has been disconnected after completion of a data transfer to the ferroelectric memory.

14. A method for fabricating a semiconductor memory device including a ferroelectric memory, the method comprising:
a first step of forming the ferroelectric memory and a nonvolatile memory on a chip, the nonvolatile memory having higher data retention capability under high temperature than the ferroelectric memory;
a second step of writing data which is unique to the chip into the nonvolatile memory after the first step has been performed;
a third step of packaging and assembling the chip after the second step has been performed; and
a fourth step of transferring at least part of the data from the nonvolatile memory to the ferroelectric memory after the third step has been performed.

15. The method of claim 14, comprising a fifth step of erasing contents of the nonvolatile memory after the fourth step has been performed.
